(19) United States
(12) Patent Application Publication
(10) Pub. No.: US 2013/0273263 A1
(43) Pub. Date: Oct. 17, 2013

(54) CVD APPARATUS AND CVD METHOD

(71) Applicant: CANON ANELVA CORPORATION, Kawasaki-shi (JP)

(72) Inventors: Ge XU, Kawasaki-shi (JP); Kazuto YAMANAKA, Kawasaki-shi (JP); Tsutomu HIROISHI, Kawasaki-shi (JP); Shogo HIRAMATSU, Kawasaki-shi (JP)

(21) Appl. No.: 13/914,837

(22) Filed: Jun. 11, 2013

Related U.S. Application Data
(63) Continuation of application No. PCT/JP2011/007296, filed on Dec. 27, 2011.

(30) Foreign Application Priority Data
Dec. 28, 2010 (JP) 2010-294007

(51) Int. Cl. C23C 16/50

(52) U.S. Cl. CPC C23C 16/50
USPC 427/569; 118/723 E

(57) ABSTRACT

The objective of the present invention is to provide a plasma CVD apparatus capable of improving the speed of carbon film deposition onto a substrate to be processed, decreasing the cleaning frequency by reducing deposition on members other than the substrate to be processed, and being manufactured inexpensively. One embodiment of the present invention is a CVD apparatus including a vacuum vessel, magnetic-field producing means for producing a magnetic field inside the vacuum vessel, plasma producing means for producing a plasma inside the vacuum vessel, and a substrate holder configured to hold a substrate inside the vacuum vessel, and the plasma producing means has an electrode provided inside the substrate holder and a power source configured to apply voltage to the electrode.

### CROSS-REFERENCE TO RELATED APPLICATIONS

This application ins a continuation application of International Application No. PCT/JP2011/07296, filed Dec. 27, 2011, which claims the benefit of Japanese Patent Application No. 2010-294007, filed Dec. 28, 2010. The contents of the aforementioned applications are incorporated herein by reference in their entireties.

### TECHNICAL FIELD

The present invention relates to a plasma CVD (Chemical Vapor Deposition) apparatus and a plasma CVD method.

### BACKGROUND ART

In plasma CVD, a thin film is formed on a surface of a substrate to be processed (a process target) by bringing a source gas for film formation to a plasma state by discharge in vacuum and decomposing the source gas by the energy of the plasma. In another method often employed, the quality of a film is improved by forming the film with ionized molecules accelerated by negative potential applied to the process target.

Particularly for carbon-based protection films such as DLC (Diamond-Like Carbon) films, an apparatus configuration and a method for forming a film on both of surfaces of a substrate to be processed are employed (see Patent Document 1).

As shown in Patent Document 1, conventionally, in forming a film on both of surfaces of a substrate to be processed, a plasma is produced within a vacuum chamber by applying high-frequency voltage to electrodes provided at positions opposite from the substrate to be processed. In this event, the voltage is applied to the substrate to be processed, and an ionized source gas is accelerated by the negative potential. Thus, a film is formed on the substrate to be processed.

### CITATION LIST

### Patent Document

Patent Document 1: Japanese Patent Application Laid-Open No. 2008-171505

### SUMMARY OF INVENTION

However, when a conventional apparatus, such as the one shown in Patent Document 1 is used to form a thick carbon film on a substrate to be processed, the film formation is slow and requires time. In addition to this problem, since a plasma is uniformly produced in spaces between the substrate to be processed and the electrodes, a film is deposited not only on the substrate to be processed, but also on the electrodes arid an inner wall of a vessel. When a film is deposited onto the electrodes or the inner wall of the vessel, film peeling occurs. Attachment of the peeled film onto the substrate to be processed results in generation of particles. Since the film formation is slow, it takes time to complete film formation on the substrate to be processed. As a result, a large amount of film is deposited onto the electrodes or the inner wall of the vessel. For this reason, cleaning has to be carried out frequently, and this lowers productivity.

Moreover, in the conventional apparatus, a high-frequency power source and a matching box have to be provided for the electrodes provided opposite from the substrate to be processed, and this leads to a problem of making the apparatus expensive.

The present invention has been made in view of these problems, and provides a plasma CVD apparatus capable of improving the speed of carbon film deposition onto a substrate to be processed, decreasing the cleaning frequency by reducing deposition on members other than the substrate to be processed, and also being manufactured inexpensively.

To solve the problem described above, the present invention is a CVD apparatus comprising a vacuum vessel, magnetic-field producing means for producing a magnetic field inside the vacuum vessel, plasma producing means for producing a plasma inside the vacuum vessel, and a substrate holder configured to hold a substrate inside the vacuum vessel, and the plasma producing means has an electrode provided inside the substrate holder and a power source configured to apply voltage to the electrode.

By using the apparatus of the present invention, the speed of carbon film deposition onto a substrate to be processed can be improved. In addition, the cleaning frequency can be decreased by reducing deposition onto members other than the substrate to be processed. Further, the apparatus according to the present invention can be manufactured less expensively than a conventional plasma CVD apparatus.

### BRIEF DESCRIPTION OF DRAWINGS

FIG. 1 is a top view of a vacuum processing apparatus according to one embodiment of the present invention.

FIG. 2 is a front view of the vacuum processing apparatus according to one embodiment of the present invention.

FIG. 3 is a side view at the vacuum processing apparatus according to the one embodiment of the present invention.

FIG. 4A is a front view of a holder according to one embodiment of the present invention.

FIG. 4B is a sectional view taken along A-A′ of the holder according to the one embodiment of the present invention.

FIG. 5 is a diagram illustrating magnetic fields and plasma produced in the vacuum processing apparatus according to the one embodiment of the present invention.

FIG. 6 is a diagram illustrating control of the strength and distribution of magnetic fields produced in a vacuum processing apparatus according to one embodiment of the present invention.

FIG. 7 is a diagram illustrating control of the strength and distribution of magnetic fields produced in a vacuum processing apparatus according to one embodiment of the present invention.

### DESCRIPTION OF EMBODIMENTS

With reference to the drawings, embodiments of the present invention are described below. However, the present invention is not limited to these embodiments. In the drawings described below, parts having the same functions are denoted by the same reference numerals, and may not be described repeatedly.

### First Embodiment

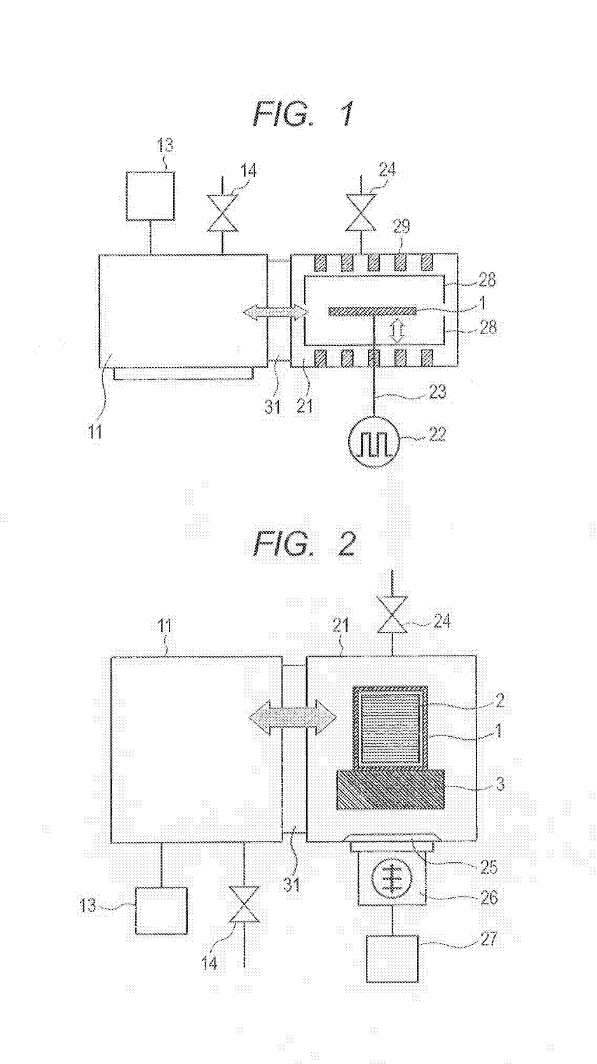

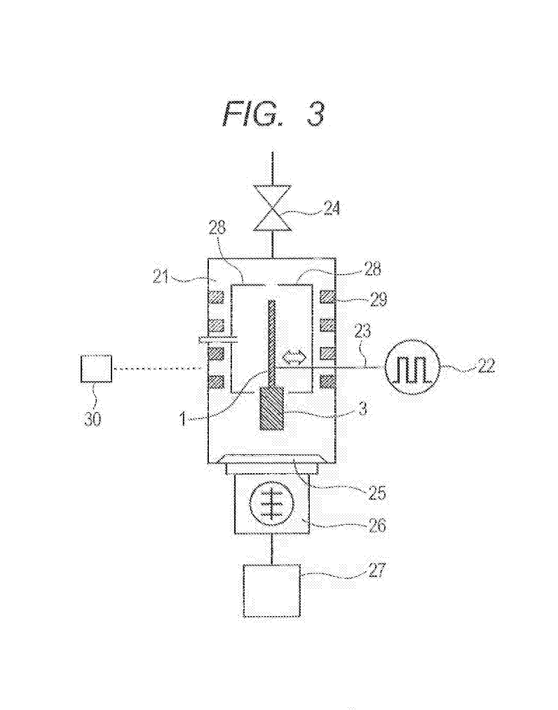

With reference to FIGS. 1 to 3 and 5, a vacuum processing apparatus according to this embodiment is described.

The vacuum processing apparatus according to this embodiment has a load lock chamber 11 and a process chamber 21 which are evacuated. The load lock chamber 11 and the process chamber 21 are structured such that they can be spatially separated by a gate valve 31. In the vacuum processing apparatus, a substrate 2 is placed into the load lock chamber 11 exposed to the atmosphere, and the load lock chamber 11 is then evacuated. Thereafter, the gate valve 31 located between the evacuated load lock chamber 11 and the vacuum-storing process chamber 21 is opened, and the substrate is transported to the process chamber 21 by a slider 3. In the process chamber 21, the transported substrate 2 is subjected to a predetermined process. Such a configuration of the apparatus is advantageous in that the process chamber 21 does not need to be exposed to the atmosphere every time a new substrate is placed. Although the vacuum processing apparatus according to this embodiment is configured by including one load lock chamber 11 and one process chamber 21, it may be configured by including multiple process chambers, depending on the process steps to be performed.

The load lock chamber 11 has exhaust means 13 and vent means 14 for the exposure to the atmosphere. For example, a dry pump is used as the exhaust means 13, and a gas introduction portion configured to introduce a N₂ (nitrogen) gas or dry air is used as the vent means 14.

The process chamber 21 is a chamber in which the substrate 2 is subjected to a process such as heating, cooling, film formation, or etching. The process chamber 21 has gas introduction means 24 for introducing a discharge gas and exhaust means. For example, the exhaust means has a turbo-molecular pump 26 and a back-pressure exhaust pump 27. Desirably, the exhaust means further has a main valve 25 or a variable orifice capable of changing the exhaust conductance. The process chamber 21 further includes a power source 22 for applying high voltage to the substrate 2, and temperature measuring means 30 for measuring the temperature of the substrate 2. For example, a radiation thermometer is used as the temperature measuring means 30.

Voltage application means applies negative high voltage to the substrate 2 via a holder 1, and includes the power supply 22 and a voltage application cylinder 23. The voltage application cylinder 23 operates the voltage application means so that the voltage application means may not be connected to the holder 1 while the holder 1 is being transported.

In the process chamber 21, shields 28 are provided surrounding the holder 1 to prevent film deposition onto an inner wall of the process chamber 21 while the substrate is processed. Magnetic-field producing means 29 is provided at the back of each shield 28. The distribution of plasma density in a space inside the process chamber 21 can be controlled during the process of the substrate by magnetic fields produced by the magnetic-field producing means 29. Permanent magnets or electromagnets can be used as the magnetic-field producing means 29. The shields 26 are electrically grounded, and function as anode upon plasma production in the process chamber 21. Note that, in the plasma CVD apparatus according to the present invention, the grounding of the shields 28 is not an essential configuration element, and a different configuration can be employed as long as the shields 28 function as anode.

A heat dissipating sheet 32 is provided between the magnetic-field producing means 29 and the shield 28. The shield 28 is heated by the plasma produced in the process chamber 21, and the heat dissipating sheet 32 prevents the magnetic-field producing means 29 from receiving the heat of the shield 28. A material having high thermal conductivity, such as aluminum, is used as the heat dissipating sheet 32. Note that the heat dissipating sheet 32 is desirably a non-magnetic material so as not to influence the lines of magnetic fields produced by file magnetic-field producing means 29.

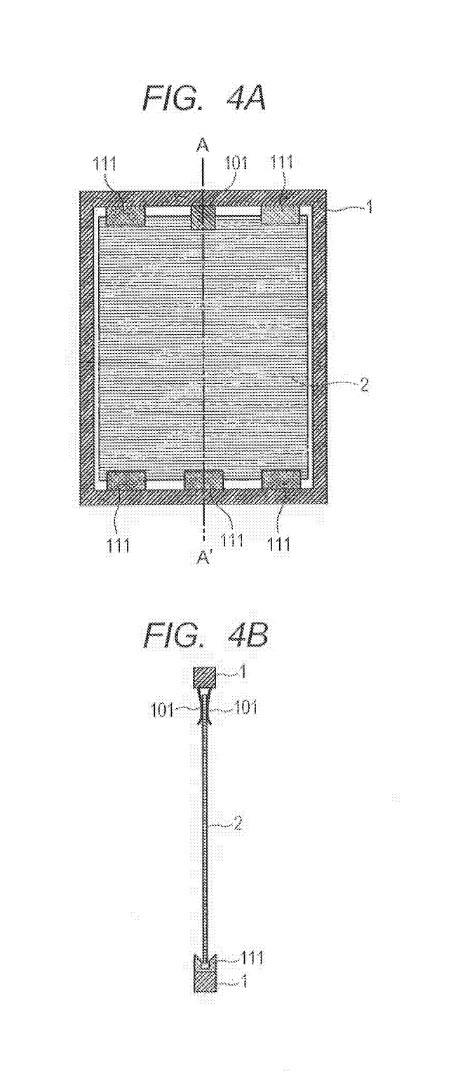

FIG. 4A shows a front view of the holder 1 holding the substrate 22. FIG. 4B shows a sectional view taken along A-A′ line in FIG. 4A. Note that FIGS. 4A and 4B do not show the slider 3.

The substrate 2 used in this embodiment is a metal sheet member having a thickness of about 0.1 mm, formed into a quadrangle of about 50×50 mm to 500×500 mm. The holder 1 includes spring support portions 101 which sandwich the substrate 2 to enable the substrate 2 to be held by its conductive holder body having a square frame shape. The holder 1 also includes guide portions 111 for preventing shaking of the substrate 2 upon its transport and preventing deformation, such as warpage, of the substrate 2 due to thermal expansion or the like. Metal plates are used for the spring support portions 101 to apply high voltage to the substrate 2 through them. For the guide portions 111, an insulating material having low thermal conductivity is used to suppress escape of heat. Further, the spring support portions 101 each have such a shape that its tip end portion extends outward so as to facilitate insertion of the substrate 2.

In this embodiment, as shown in FIGS. 4A and 4B, the spring support portions 101 are provided at a single place on an upper center portion of the substrate 2, and hold the substrate. Being members for preventing flexure of the substrate 2, the guide portions 111 do not need to be in contact with the substrate 2.

The sheet substrate 2 is held by the holder 1 which is substrate holding means supported by the slider 3. Thus, while being held vertically, the substrate 2 is processed on its both surfaces. Since high voltage is applied to she substrate 2 via the spring support portions 101 of the holder 1, the potential of the holder 1 and that of the substrate 2 become substantially equal.

The holder 1 transported from the load lock chamber 11 is stopped at a predetermined position (processing position) in the process chamber 21, and the gate valve 31 is closed to isolate the process chamber 21 from other processing chambers.

Next, a description is given of a film formation process performed on the substrate 2 in the process chamber 21.

In this embodiment, as an example, a DLC film is formed on the substrate 2. It is desirable that the DLC film formation on the substrate 2 be performed with the substrate 2 being heated. Hence, a heating process is performed on the substrate 2 prior to the film formation. First, an inert gas is introduced into the process chamber 21. Next, the voltage application cylinder 23 is driven to bring the holder 1 and the voltage application means into electrical contact with each other. High voltage which is applied by the voltage application means is preferably direct-current (DC) voltage of pulse DC voltage, and application of the high voltage to the substrate 2 produces a plasma in the process chamber 21. Desired film properties can easily by obtained by application of direct-current voltage because direct-current voltage is constant compared to alternating-current voltage. Further, when a plasma is produced in the plasma chamber 21 by applying voltage from a direct-current power supply, the power supply does not need to be a high-frequency power supply. This makes unnecessary a design considering the matching box or voltage resistance, and therefore allows the apparatus to be manufactured less expensively than a conventional apparatus. The temperature of the substrate 2 increases by ion bombardment by the plasma. In this event, since the plasma is confined near the substrate 2 by the magnetic fields, the substrate 2 can be speedily heated.

After the substrate 2 is heated, a hydrocarbon gas is introduced to the process chamber 21. The hydrocarbon gas is decomposed by the plasma produced inside the process chamber 21, and ions are attracted to the substrate 2 due to the negative voltage applied to the substrate 2. Thus, a carbon film is formed on the substrate.

In this event, as shown in FIG. 5, magnetic fields are produced in the process chamber 21 by the magnetic-field producing means 29 provided at the back of each shield 28. The plasma produced in the process chamber 21 is confined near the substrate 2 by these magnetic fields. For this reason, in this embodiment, carbon film deposition onto the shields 28 functioning as anode is suppressed. Further, even if the film does attach to the shields 28, the film formed there is a polymeric film because ion bombardment occurs less. For this reason, film cracking or peeling can be prevented, and therefore generation of particles can be suppressed. Further, if the shields 28 are grounded, no voltage is applied to the shields 28. Hence, the shields 28 do not actively attract the ions. For this reason, further suppression of film attachment to the shields 28 can be achieved.

Thus, with the plasma CVD apparatus according to this embodiment, film attachment to the inner wall of the process chamber 21 is reduced by the shields 28, and moreover, film attachment to the shields 28 can be suppressed. Consequently, the cleaning frequency is decreased, which can contribute to improvement in productivity.

Meanwhile, since the plasma is confined near the substrate 2 by the magnetic fields, the speed of carbon film deposition onto the substrate 2 is increased. For this reason, film formation can be accomplished with a shorter time than in a conventional plasma CVD apparatus.

In a conventional plasma CVD apparatus such as the one shown in Patent Document 1, electrodes for plasma production are provided at positions facing the substrate, and consequently a plasma is produced at a location away from the substrate. For this reason, heating of the substrate and film formation on the substrate by the plasma require time. In contrast, in the plasma CVD apparatus according to the present invention, voltage is applied to the holder 1 and the substrate 2. Thus, a plasma can be produced near the substrate 2, and then confined near the substrate 2 by magnetic fields. Hence, the plasma CVD apparatus according to the present invention can offer an effect of heating the substrate 2 more speedily than a conventional one and an effect of forming a carbon film on the substrate 2 more speedily than a conventional one.

Although DLC film formation is described as an example in this embodiment, the plasma CVD apparatus and the plasma CVD method according to the present invention are also applicable to other types of processes.

### EXAMPLE 1

An example is shown below of forming DLC films on the substrate 2 by using the plasma CVD apparatus according to this embodiment.

First, the substrate 2 was transported to the process chamber 21, and the gate valve 31 was closed. Then, an Ar gas was introduced from the gas introduction portion 24 at 500 sccm (standard cc/min). By this introduction of the Ar gas, the internal pressure of the process chamber 21 was brought to 20 Pa.

With magnetic fields being produced inside the process chamber 21 by permanent magnets used as the magnetic-field producing means 29, a pulse voltage of minus 400 V was applied by the voltage application means to produce a plasma. The substrate 2 was heated by the plasma for about five seconds to reach a temperature or about 500° C. By thus performing the heating process of the substrate by the plasma of the Ar gas before forming the DLC films, the surface of the substrate is cleaned, and adsorbed gas is removed. Thereby, the adhesiveness between the substrate and the DLC films improve.

Next, an ethylene gas was introduced into the process chamber 21 at 250 sccm to bring the pressure of the process chamber 21 to 20 Pa. Simultaneously, a pulse voltage of minus 1000 V was applied to the substrate 2 to produce a plasma. By keeping applying the voltage for about 100 seconds, DLC films each haying a thickness of about 100 nm were formed.

Although the film formation process is perforated on both surfaces of the substrate 2 in this embodiment, the plasma CVD apparatus according to the present invention is also useful when the film formation is performed on only one surface.

In addition, although the magnetic-field producing means 29 is provided between each shield 28 and the inner wall of the process chamber 21 in this embodiment, the magnetic-field producing means 29 may be provided outside the process chamber 21 as long as they can produce magnetic fields between the shields 28 and the process chamber 21. However, if the magnetic-field producing means 29 is provided between the shield 28 and the inner wall of the process chamber 21, strong magnetic fields are produced at the surface of the shield 28 on the substrate side. Thus, when permanent magnets are used as the magnetic-field producing means 29, magnetic fields of a target strength can be produced with less and smaller permanent magnets. When electromagnets are used as the magnetic-field producing means 29, magnetic fields of a target strength can be produced with smaller current.

As for the placement of the magnetic-field producing means 29, in FIGS. 1 to 3 and 5, the magnetic-field producing means 29 are placed only at such positions that their magnetic poles face the process surfaces of the substrate 2. However, the magnetic-field producing means 29 may be provided at other positions. Further, although multiple magnetic-field producing means 29 are provided at the back of each shield 28 in FIGS. 1 to 3 and 5, the magnetic-field producing means 29 may be a large single piece. Employing multiple magnetic-field producing means 29 is advantageous in that, for example, the price is less expensive than the magnetic-field producing means 29 formed as a single piece, that the number of the magnetic-field producing means 29 can be appropriately changed according to a process to be performed, and that precise control can be performed by causing magnetic-field producing means driving means to be described later to move the multiple magnetic-field producing means 29 individually.

### Second Embodiment

As described above, in the first embodiment, magnetic fields are produced by the magnetic-field producing means 29 to confine a plasma near the substrate 2. In this event, the distribution of plasma density can be changed by causing the magnetic-field producing means 29 to change the strength of the magnetic fields produced in the process chamber 21. Thereby, the temperature of the substrate 2 and the speed of film formation can be controlled.

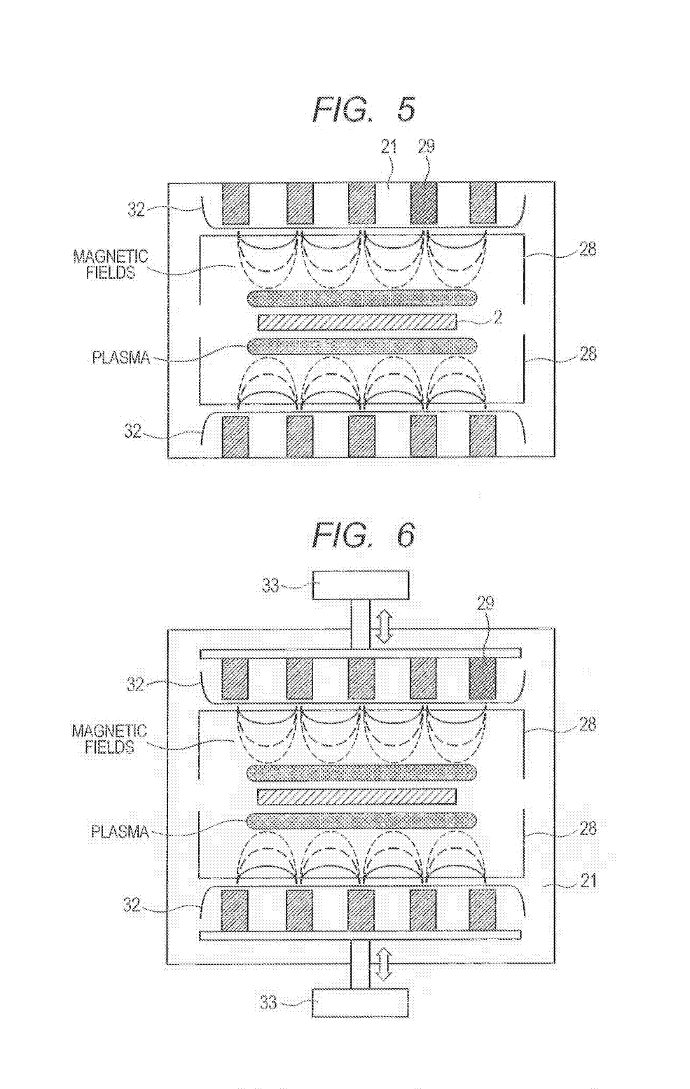

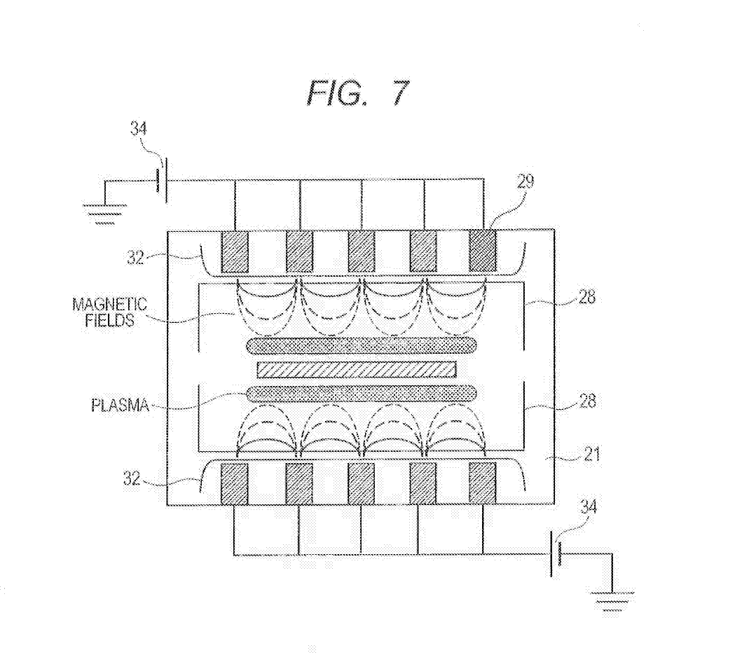

FIGS. 6 and 7 are diagrams each illustrating a plasma CVD apparatus according to this embodiment, in which the distribution and strength of magnetic fields produced by the magnetic-field producing means 29 are changed.

FIG. 6 is a diagram illustrating a plasma CVD apparatus using permanent magnets as the magnetic-field producing means 29. This plasma CVD apparatus includes magnetic-field producing means driving means 33 capable of moving the magnetic-field producing means 29 in a direction in which the magnetic-field producing means 29 faces the substrate 2. The magnetic-field producing means driving means 33 moves the magnetic-field producing means 29 in such a direction as to increase or decrease the volume of a space between the magnetic-field producing means 29 and the holder 1 or the substrate 2, e.g., in a such a direction as to change the distance between the magnetic-field producing means 29 and the substrate 2 or a direction normal to the substrate 2. Since the moving direction only has to be one to increase or decrease the volume of the space between the magnetic-field producing means 29 and the holder 1 or the substrate 2, the magnetic-field producing means may be moved in a direction shifted from a direction normal to the substrate 2 by a certain angle. Thereby, the distribution of magnetic fields in the space between the magnetic-field producing means 22 and the substrate 2 is changed. which can consequently change the distribution of plasma density in the process chamber 21. In FIG. 6, all the magnetic-field producing means 29 are uniformly moved by the magnetic-field producing means driving means 33, but each magnetic-field producing means may be provided with its own magnetic-field producing means driving means. In a case where the magnetic-field producing means driving means is provided for each magnetic-field producing means, the distance between each magnetic-field producing means and the substrate can be adjusted. Thus, the film thickness distribution of film formed on the substrate 2, for example, can be controlled more precisely.

FIG. 7 is a diagram illustrating a plasma CVD apparatus using electromagnets as the magnetic-field producing means 29. The plasma CVD apparatus includes an electromagnet power source 34 for applying current to the electromagnets to produce magnetic fields in the process chamber 21. By changing the amount of current to be supplied from the electromagnet power source 34, the magnetic fields produced in the process chamber 21 can be changed. Although the electromagnet power source 34 applies voltage uniformly to all the magnetic-field producing means 29 to cause current to flow therethrough in FIG. 7, the electromagnetic power source may be provided for each magnetic-field producing means. When the electromagnetic power source is provided for each magnetic-field producing means, the magnetic fields produced by the respective magnetic-field producing means can be adjusted individually, and thus the film thickness distribution of film formed on the substrate 2, for example, can be controlled more precisely. Further, like the apparatus shown in FIG. 6, the apparatus may be provided with the magnetic-field producing means driving means capable of changing the positional relation between the electromagnets and the substrate.

When the plasma CVD apparatus according to this embodiment is used, feeding back the temperature of the substrate 2 measured by the temperature measuring means 30 to the magnetic-field producing means driving means 33 and the electromagnet power source 34 enables, for example, maintaining the temperature of the substrate 2 to be constant during the film formation process, and maintaining discharge current to be constant, the discharge current being changed when a carbon film is attached on the shield 28.

Note that the above embodiments of the prevent invention can be changed variously without departing from the gist of the present invention.

1. A CVD apparatus characterized in that
the apparatus comprises:
a vacuum vessel;
magnetic-field producing means for producing a magnetic field inside the vacuum vessel;
plasma producing means for producing a plasma inside the vacuum vessel;
a substrate holder configured to hold a substrate inside the vacuum vessel; and
a shield provided inside the vacuum vessel at a position opposite from the substrate holder,
the magnetic-field producing means is provided between an inner wall of the vacuum vessel and the shield,
the shield is grounded, and
the plasma producing means has an electrode provided inside the substrate holder and a power source configured to apply voltage to the electrode.

2. The CVD apparatus according to claim 1, characterized in that the power source is a direct-current power source configured to apply direct-current voltage to the electrode.

3. The CVD apparatus according to claim 1, characterized in that the apparatus comprises moving means for moving the magnetic-field producing means in such a direction as to increase or decrease a volume of a space between the magnetic-field producing means and the substrate holder.

4-5. (canceled)

6. The CVD apparatus according to claim 1, characterized in that the apparatus comprises a heat dissipating sheet between the magnetic-field producing means and the shield.

7. The CVD apparatus according to claim 1, characterized in that the plasma is a plasma of a hydrocarbon gas, and a carbon film is formed on the substrate by the plasma of the hydrocarbon gas.

8. A CVD apparatus characterized in that
the apparatus comprises:
a vacuum vessel;
magnetic-field producing means for producing a magnetic field inside the vacuum vessel;
a substrate holder having an electrode thereinside and configured to hold a substrate inside the vacuum vessel;
a power source configured to apply voltage for producing a plasma in the vacuum vessel to the electrode; and
a shield provided inside the vacuum vessel at a position opposite from the substrate holder,
the magnetic-field producing means is located between an inner wall of the vacuum vessel and the shield,
the shield is grounded, and
an electrode connected to the power source is not provided on an opposite side from the substrate holder.

9. The CVD apparatus according to claim 8, characterized in that the power source is a direct-current power source configured to apply direct-current voltage to the electrode.

10. A CVD method for performing a film formation process on a substrate in a vacuum vessel having thereinside a substrate holder which is holding the substrate, magnetic-field producing means which is producing a magnetic field, and a shield provided at a position opposite from the substrate holder and grounded, the magnetic field-producing means being located between an inner wall of the vacuum vessel and the shield, the method comprising the steps of:
introducing a source gas into a space between the magnetic-field producing means and the substrate holder;
producing a plasma of the source gas by applying voltage to the substrate holder; and
forming a film on the substrate by the plasma of the source gas.

11. The CVD method according to claim 10 further comprising, before the step of introducing the source gas, the steps of:
introducing an inert gas into the space between the magnetic-field producing means and the substrate holder;
producing a plasma of the inert gas by applying voltage to the substrate holder; and
heating the substrate by the plasma of the inert gas.

12. The CVD method according to claim 10, characterized in that the voltage is direct-current voltage.

13. The CVD method according to claim 10, characterized in that the plasma of the source gas is confined near the substrate by the magnetic field.

14. The CVD method according to claim 10, characterized in that the magnetic field is changed by moving the magnetic-field producing means in such a direction as to increase or decrease a volume of the space between the magnetic-field producing means and the substrate holder.

15. The CVD method according to claim 10, characterized in that the source gas is a hydrocarbon gas, and a carbon film is formed on the substrate by the plasma of the hydrocarbon gas.

16. The CVD apparatus according to claim 2, characterized in that the apparatus comprises moving means for moving the magnetic-field producing means in such a direction as to increase or decrease a volume of a space between the magnetic-field producing means and the substrate holder.
